(19) United States
(12) Patent Application Publication
(10) Pub. No.: US 2024/0288284 A1
(43) Pub. Date: Aug. 29, 2024

(54) PIEZOELECTRIC COIL WITH A SENSOR AND ELECTRONIC APPARATUS

(71) Applicant: SONY GROUP CORPORATION, Tokyo (JP)

(72) Inventors: Nobuyuki NAGAI, Tokyo (JP); Shuta KITADE, Tokyo (JP); Toru UDAKA, Tokyo (JP); Miki ENDO, Tokyo (JP); Yuichi ISHIDA, Tokyo (JP)

(21) Appl. No.: 18/573,304

(22) PCT Filed: Mar. 24, 2022
(86) PCT No.: PCT/JP2022/013956

§ 371 Date: Dec. 21, 2023

(30) Foreign Application Priority Data
Jul. 27, 2021 (JP) 2021-122636

(51) Int. Cl. G01D 5/14

(52) U.S. Cl. CPC G01D 5/14

(57) ABSTRACT

[Object] To provide a technology relating to a piezoelectric coil or the like capable of performing displacement sensing.

[Solving Means] A piezoelectric coil with a sensor according to the present technology includes: a piezoelectric coil; and a sensor. The piezoelectric coil includes a coil-shaped core and one or more first piezoelectric members that are helical relative to the core, and is expandable and contractable in an expanding/contracting direction. The sensor detects a displacement due to expansion and contraction of the piezoelectric coil.

### TECHNICAL FIELD

The present technology relates to a technology relating to a piezoelectric coil and the like.

### BACKGROUND ART

The following Patent Literature 1 describes a piezoelectric actuator configured by a band-shaped piezoelectric element helically wound around the surface of a coil spring.

In this piezoelectric actuator, when an electric field is applied to the piezoelectric element, the piezoelectric element deforms in the longitudinal direction. Then, this deformation of the piezoelectric element generates a torsional moment in the cross section of the coil spring, and the coil spring deforms in the axial direction.

Note that examples of the technology relating to the present technology include the following Patent Literature 2.

### CITATION LIST

### Patent Literature

Patent Literature 1: Japanese Patent Application Laid-open No. 1994-216424
Patent Literature 2: Japanese Patent Application Laid-open No. 2019-161823

### DISCLOSURE OF INVENTION

### Technical Problem

In this type of coil element, there is a need for a technology capable of performing displacement sensing.

In view of the circumstances as described above, it is an object of the present technology to provide a technology relating to a piezoelectric coil or the like capable of performing displacement sensing.

### Solution to Problem

A piezoelectric coil with a sensor according to the present technology includes: a piezoelectric coil; and a sensor.

The piezoelectric coil includes a coil-shaped core and one or more first piezoelectric members that are helical relative to the core, and is expandable and contractable in an expanding/contracting direction.

The sensor detects a displacement due to expansion and contraction of the piezoelectric coil.

As a result, it is possible to provide a technology relating to a piezoelectric coil or the like capable of performing displacement sensing.

An electronic apparatus according to the present technology includes a piezoelectric coil with a sensor.

The piezoelectric coil with a sensor includes a piezoelectric coil, and a sensor.

The piezoelectric coil includes a coil-shaped core and one or more first piezoelectric members that are helical relative to the core, and is expandable and contractable in an expanding/contracting direction.

The sensor detects a displacement due to expansion and contraction of the piezoelectric coil.

### BRIEF DESCRIPTION OF DRAWINGS

FIG. 1 is a side view showing a piezoelectric coil with a sensor according to a first embodiment.

FIG. 2 is a top view showing the piezoelectric coil with a sensor.

FIG. 3 is a perspective view showing the piezoelectric coil with a sensor.

FIG. 4 is a cross-sectional view of the piezoelectric coil with a sensor.

FIG. 5 is a diagram for describing an operation of the piezoelectric coil with a sensor.

FIG. 6 is a diagram showing a simulation result in a first sample (second piezoelectric member: PZT).

FIG. 7 is a diagram showing a simulation result in a second sample (second piezoelectric member: P(VDF-TrFE)).

FIG. 8 is a diagram showing another example of signal detection in displacement sensing.

FIG. 9 is a perspective view showing a piezoelectric coil with a sensor according to a second embodiment.

FIG. 10 is a cross-sectional view of the piezoelectric coil with a sensor in a plane perpendicular to the length direction of a core.

FIG. 11 is a diagram showing a piezoelectric coil with a sensor according to each modified example.

### MODE(S) FOR CARRYING OUT THE INVENTION

### First Embodiment

### <Overall Configuration and Configurations of Respective Units>

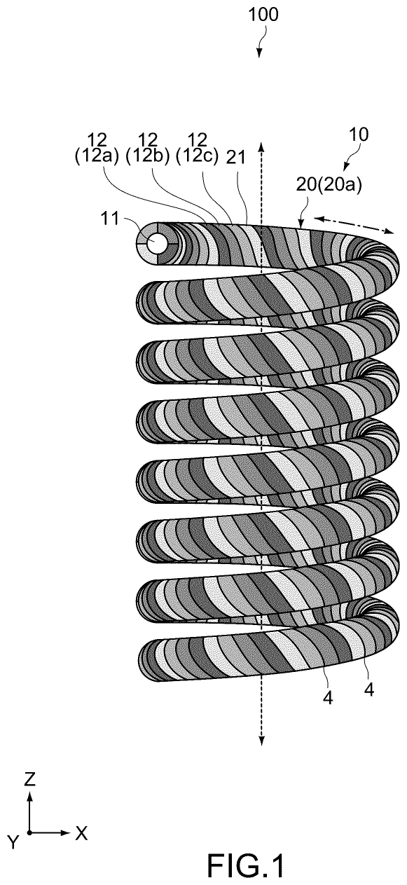

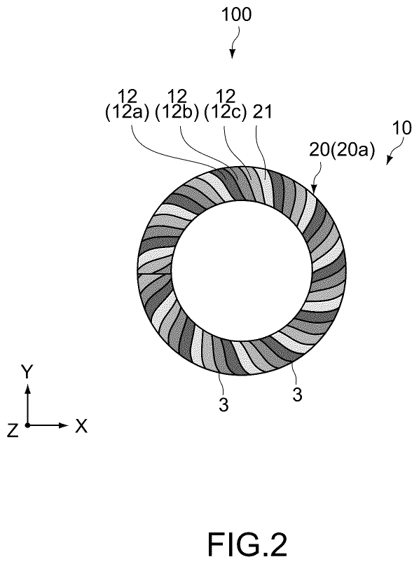

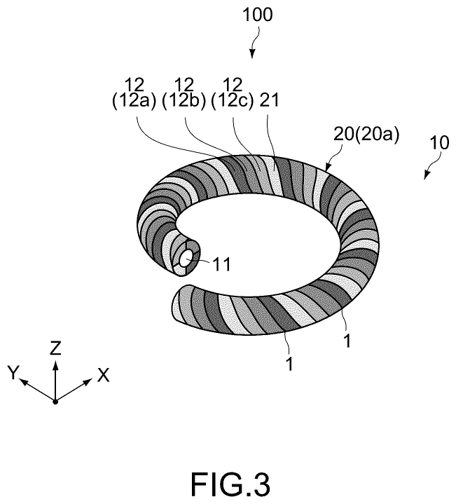

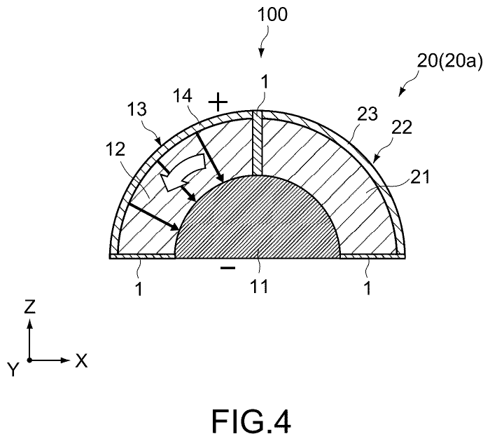

FIG. 1 is a side view showing a piezoelectric coil with a sensor 100 according to a first embodiment. FIG. 2 is a top view showing the piezoelectric coil with a sensor 100. FIG. 3 is a perspective view showing the piezoelectric coil with a sensor 100. FIG. 4 is a cross-sectional view of the piezoelectric coil with a sensor 100.

In FIG. 1 to FIG. 3, illustration of a surface electrode 14 and a detection electrode 23 shown in FIG. 4 is omitted. Further, in FIG. 3, the basic unit for one circle in the piezoelectric coil with a sensor 100 is shown. Further, in FIG. 4, half of the cross section of the piezoelectric coil with a sensor 100 is partially shown.

The piezoelectric coil with a sensor 100 is formed to have a coil spring shape and is expandable and contractable in the direction of the central axis of the coil (expanding/contracting direction: see the dot-dash line: Z-axis direction). Note that the overall number of turns, the number of turns per unit length, and the like in the piezoelectric coil with a sensor 100 can be arbitrarily set.

The piezoelectric coil with a sensor 100 includes a piezoelectric coil 10 that is expandable and contractable in the direction of the central axis of the coil, and a displacement sensor 20 capable of detecting a displacement due to expansion and contraction of the piezoelectric coil 10. The value of the displacement of the piezoelectric coil 10 detected by the displacement sensor 20 is used for feedback control of the piezoelectric coil with a sensor 100, and the like.

The piezoelectric coil 10 includes a coil-shaped core 11 that is expandable and contractable in the expanding/contracting direction (Z-axis direction), three first piezoelectric members 12 that are helically wound around the core 11, and a first electrode portion 13 that applies an electric field in the thickness direction of the first piezoelectric member 12. Further, the displacement sensor 20 includes one second piezoelectric member 21 that are helically wound around the core 11, and a second electrode portion 22 that detects a voltage generated by the second piezoelectric member 21.

The core 11 is formed to have a coil spring shape, and has a circular cross section (cross section perpendicular to the length direction of the core 11). Note that the cross section of the core 11 may be elliptical, polygonal, or the like, and the shape of this cross section is not particularly limited.

The core 11 is formed of at least one material selected from graphite, an Mg alloy, Al, Ti, SUS, W, Au, Ag, Cu, Pt, ceramics, or a polymer resin.

The first piezoelectric member 12 and the second piezoelectric member 21 are each formed into a band shape that is long in the length direction, short in the width direction, and thin in the thickness direction. Although the number of first piezoelectric members 12 is three in the example shown in FIG. 1 to FIG. 4, the number of first piezoelectric members 12 may be 1, 2, 4, . . . , or the like, and is not particularly limited.

Note that in the description in the present specification, in the case where a plurality of first piezoelectric members 12 is not particularly distinguished from each other, they are referred to as the “first piezoelectric member 12”. In the case where the plurality of first piezoelectric members 12 is particularly distinguished from each other, they are referred to as the “first piezoelectric member 12a”, “first piezoelectric member 12b”, “first piezoelectric member 12c” . . . , in accordance with the number of first piezoelectric members 12.

The first piezoelectric member 12 and the second piezoelectric member 21 are alternately helically wound around the core 11 in the order of, for example, the first piezoelectric member 12a, the first piezoelectric member 12b, the first piezoelectric member 12c, the second piezoelectric member 21, the first piezoelectric member 12a, the first piezoelectric member 12b, the first piezoelectric member 12c, the second piezoelectric member 21, . . . , in the direction along the length direction of the core 11 (see FIG. 1: dot-dash line).

The three first piezoelectric members 12 are aligned in the direction along the length direction of the core 11. The second piezoelectric member 21 is interposed between the three first piezoelectric members 12 in the direction along the length direction of the core 11, and is disposed in the direction along the length direction of the core 11 with respect to the three first piezoelectric members 12. Further, the second piezoelectric member 21 is disposed alternately with the three first piezoelectric members 12 in the direction along the length direction of the core 11.

The first piezoelectric member 12 and the second piezoelectric member 21 are wound at a predetermined angle (e.g., approximately 45°±15°: the length direction of the core 11 is 0°) with respect to the length direction of the core 11 (see FIG. 1: dot-dash line).

The piezoelectric members 12 and 21 are each formed using, as a base material, at least one material selected from, for example, Pb(Zr,Ti)O₃ [PZT], PbTiO₃, Pb(Mg_{1/3}Nb_{2/3})O₃—PbTiO₃ [PMN-PT], Pb(Zn_{1/3}Nb_{2/3})O₃—PbTiO₃ [PZN-PT], BaTiO₃ [BT], (K, Na)NbO₃ [KNN], KNbO₃, NaNbO₃, (K,Na,Li)NbO₃, (K,Na,Li)(Nb,Ta,Sb)O₃, (Sr,Ba)Nb₂O₆, (Sr, Ca)NaNb₅O₁₅, (Na, K)Ba₂NbO₁₅, BiFeO₃, Bi₄Ti₃O₁₂, (Bi_{1/2}K_{1/2})TiO₃, (Bi_{1/2}Na_{1/2})TiO₃, BaTiO₃—(Bi_{1/2}K_{1/2})TiO₃, BaTiO₃—(Bi_{1/2}Na_{1/2})TiO₃, AlN, LiNbO₃, LiTaO₃, alpha-SiO₂, GaPO₄, LiB₄O₇, La₃Ga₅SiO₁₄, La₃Ta_{0.5}Ga_{5.5}O₁₄, MgSiO₃, ZnO, halide perovskite, polyvinylidene fluoride [PVDF], polylactic acid [PLLA], cellulose, or polypeptide.

The first piezoelectric member 12 and the second piezoelectric member 21 may be formed of the same material or may be formed of different materials. In the case where the first piezoelectric member 12 and the second piezoelectric member 21 are formed of different materials, the second piezoelectric member 21 may be formed of a material softer (lower Young's modulus) than the first piezoelectric member 12.

For example, the first piezoelectric member 12 may be formed of PZT, and the second piezoelectric member 21 may be formed of polyvinylidene fluoride [PVDF], polylactic acid [PLLA], or the like. In this case, it is possible to reduce the influence of the displacement sensor 20 (second piezoelectric member 21) restricting the movement of the piezoelectric coil with a sensor 100 when it expands and contracts in the expanding/contracting direction.

Note that between the first piezoelectric members 12 adjacent to each other in the length direction of the core 11 and between the first piezoelectric member 12 and the second piezoelectric member 21 adjacent to each other, an insulation portion 1 for electrically insulating them is interposed. As the material used for the insulation portion 1, a material that has insulating properties and has flexibility relatively higher than those of the materials used for the first piezoelectric member 12 and the second piezoelectric member 21 is typically used. Examples of the material satisfying this condition include a synthetic resin and a synthetic resin foam.

Note that the reason why a material having high flexibility is used as the material used for the insulation portion 1 is that the first piezoelectric member 12 and the second piezoelectric member 21 are prevented from being damaged by absorbing, when the first piezoelectric member 12 and the second piezoelectric member 21 are distorted, the influence of pressure, friction, and the like exerted by the first piezoelectric member 12 and the second piezoelectric member 21 on the adjacent piezoelectric member, with the insulation portion 1.

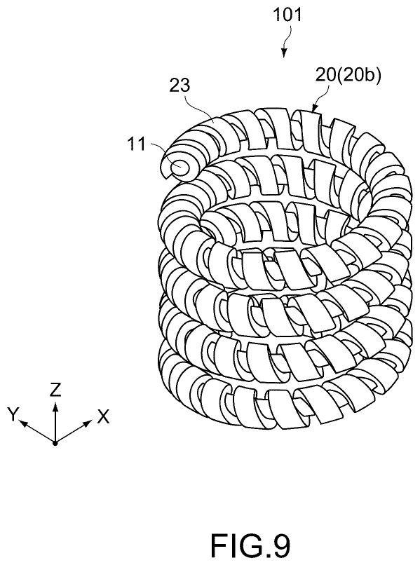

Note that the insulation portion 1 may be a gap formed between the first piezoelectric members 12 adjacent to each other and between the first piezoelectric member 12 and the second piezoelectric member 21 adjacent to each other (e.g., see FIG. 9 described below).

The first electrode portion 13 is configured to be capable of applying a voltage to the first piezoelectric member 12 in the thickness direction of the first piezoelectric member 12. Although a voltage is applied in the thickness direction of the first piezoelectric member 12 in this embodiment, a voltage may be applied in the length direction of the first piezoelectric member 12. The first piezoelectric member 12 is distorted when a voltage is applied by the first electrode portion 13. At this time, the expansion and contraction of the first piezoelectric member 12 in the longitudinal direction contributes to the deformation in the direction of the central axis of the piezoelectric coil 10 (see FIG. 1: dotted line).

The first electrode portion 13 includes the core 11 and the surface electrode 14 that sandwiches the first piezoelectric member 12 between the surface electrode 14 and the core 11 in the thickness direction of the first piezoelectric member 12. One of the core 11 and the surface electrode 14 is a positive electrode, and the other is a negative electrode.

The surface electrode 14 is formed of various materials such as a metal, and is provided in a layer on the surface of the first piezoelectric member 12 so as to cover the entire surface of the first piezoelectric member 12. The surface electrode 14 is provided individually for each of the three first piezoelectric members 12, and is helical relative to the core 11, similarly to the first piezoelectric member 12.

The second electrode portion 22 is configured to be capable of detecting a voltage generated in the thickness direction of the second piezoelectric member 21 in accordance with the expansion and contraction of the piezoelectric coil 10. Although a voltage generated in the thickness direction of the second piezoelectric member 21 is detected in this embodiment, a voltage generated in the length direction of the second piezoelectric member 21 may be detected.

The second electrode portion 22 includes the detection electrode 23 provided on the surface of the second piezoelectric member 21. The detection electrode 23 is formed of various materials such as a metal, and is provided in a layer on the surface of the second piezoelectric member 21 so as to cover the entire surface of the second piezoelectric member 21. The detection electrode 23 is helical relative to the core 11, similarly to the second piezoelectric member 21.

In this embodiment, the core 11 has two roles as a coil spring and as part of the first electrode portion 13. In the case where the core 11 has a role as part of the first electrode portion 13 as described above, a material having relatively high conductivity (e.g., metals such as graphite, an Mg alloy, Al, Ti, SUS, W, Au, Ag, Cu, Pt) is used as the material of the core 11.

Meanwhile, an electrode layer may be specially formed on the surface of the core 11 by deposition, sputtering, coating, or the like. That is, an electrode layer (back electrode) may be interposed between the surface of the core 11 and the back surface of the first piezoelectric member 12. In this case, since the core 11 does not need to have a role as part of the first electrode portion 13, an insulator or the like can also be used as the material of the core 11.

### <Number of First Piezoelectric Members 12>

Here, although the number of first piezoelectric members 12 is not particularly limited in this embodiment, it has been found from a simulation result that when the number of first piezoelectric members 12 is two or more, the piezoelectric response performance of the piezoelectric coil 10 is improved as compared with the case where the number of first piezoelectric members 12 is one.

The piezoelectric response performance includes a strain and a generated force. The strain refers to the rate at which the piezoelectric coil 10 is distorted (contracted) in the direction of the central axis of the coil (see FIG. 1: dotted line) when a predetermined electric field is applied to the first piezoelectric member 12, as compared with the case where no electric field is applied. Further, the generated force refers to a force generated by the piezoelectric coil 10 in the direction of the central axis of the coil when a predetermined electric field is applied to the first piezoelectric member 12.

In the case where the number of first piezoelectric members 12 is two or more, both the strain and generated force are improved as compared with the case where the number of first piezoelectric members 12 is one.

Meanwhile, it has also been found from a simulation result that there is little point in increasing the number of first piezoelectric members 12 without limit, and the strain and generated force tend to be saturated when the number of first piezoelectric members 12 reaches a certain level or more.

For this reason, from the viewpoint of improving the piezoelectric performance of the piezoelectric coil 10, the number of first piezoelectric members 12 is favorably within the range of 2 to 10, more favorably within the range of 2 to 7, and still more favorably within the range of 3 to 5.

### <Operation Description>

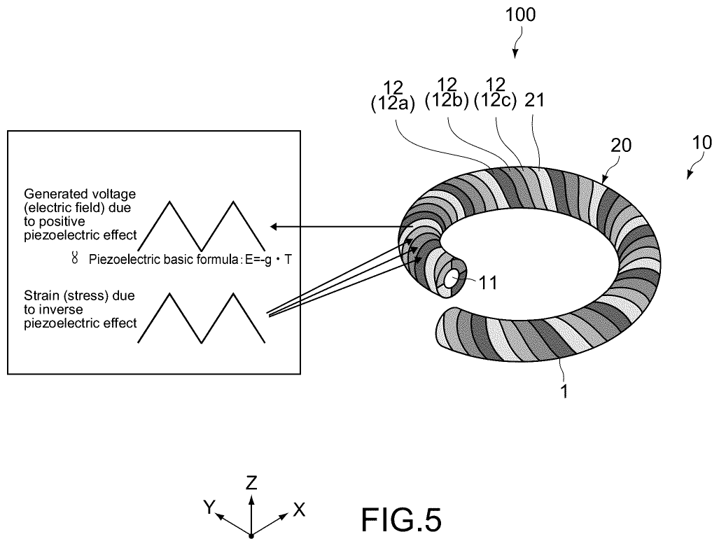

Next, an operation of the piezoelectric coil with a sensor 100 according to the first embodiment will be described. FIG. 5 is a diagram for describing an operation of the piezoelectric coil with a sensor 100.

First, a drive voltage is applied to each of the three first piezoelectric members 12 via the first electrode portion 13 (surface electrode 14). In accordance with the application of a drive voltage, the three first piezoelectric members 12 are distorted (inverse piezoelectric effect), and a stress is generated on the core 11. As a result, the core 11 expands and contracts in the expanding/contracting direction, and the entire piezoelectric coil with a sensor 100 expands and contracts in the expanding/contracting direction.

Further, the stress generated in the core 11 is transmitted to the second piezoelectric member 21 through the core 11. As a result, the second piezoelectric member 21 is distorted, and a voltage (electric field) is generated in the second piezoelectric member 21 (positive voltage effect). The piezoelectric basic formula at this time is represented by E=−g·T. Note that E represents an electric field, g represents a piezoelectric output constant, and T represents a stress.

The voltage generated by the second piezoelectric member 21 is extracted by the second electrode portion 22 (detection electrode 23). The magnitude of the voltage generated by the second piezoelectric member 21 is correlated with the degree of expansion and contraction of the piezoelectric coil with a sensor 100. Therefore, the displacement (degree of expansion and contraction of the piezoelectric coil 10) of the piezoelectric coil with a sensor 100 can be measured on the basis of the generated voltage of the second piezoelectric member 21. Information regarding the displacement of the piezoelectric coil with a sensor 100 is used for feedback control for accurately driving the piezoelectric coil with a sensor 100, and the like.

### <Piezoelectric Actuator and Power Generation Element>

Here, although a case where the piezoelectric coil 10 is used as a piezoelectric actuator will be mainly described in this embodiment, the piezoelectric coil 10 may be used as a power generation element.

In the case where the piezoelectric coil 10 is used as a piezoelectric actuator, when a voltage is applied to the first piezoelectric member 12, the first piezoelectric member 12 is distorted (inverse piezoelectric effect), and the piezoelectric coil 10 expands and contracts in the expanding/contracting direction. Meanwhile, in the case where the piezoelectric coil 10 is used as a power generation element, when the piezoelectric coil 10 expands and contracts in the expanding/contracting direction due to an external force, the first piezoelectric member 12 is distorted and the first piezoelectric member 12 generates electric power (positive piezoelectric effect).

Note that the first electrode portion 13 is used as an electrode for applying a voltage to the first piezoelectric member 12 in the case where the piezoelectric coil 10 is used as a piezoelectric actuator, and the first electrode portion 13 is used as an electrode for extracting electric power generated by the first piezoelectric member 12 in the case where the piezoelectric coil 10 is used as a power generation element.

In the case where the piezoelectric coil 10 is used as a piezoelectric actuator, information regarding a displacement of the piezoelectric coil 10 taken out from the second electrode portion 22 when the second piezoelectric member 21 is distorted is used for feedback control for accurately driving the piezoelectric coil 10.

Further, in the case where the piezoelectric coil 10 is used as a power generation element, information regarding a displacement of the piezoelectric coil 10 taken out from the second electrode portion 22 when the second piezoelectric member 21 is distorted is used for, for example, the following purposes. Here, assumption is made that the piezoelectric coil 10 expands and contracts in the expanding/contracting direction by a device that generates a mechanical external force. In this case, assumption is made that the upper limit is set in the direction in which the piezoelectric coil 10 expands, and the lower limit is set in the direction in which the piezoelectric coil 10 contracts.

In this case, whether or not the displacement of the piezoelectric coil 10 exceeds the upper limit and whether or not the displacement of the piezoelectric coil 10 falls below the lower limit are determined on the basis of the information regarding the displacement of the piezoelectric coil 10. Then, in the case where the displacement of the piezoelectric coil 10 exceeds the upper limit or falls below the lower limit, the operation of the device that generates a mechanical external force is restricted such that the piezoelectric coil 10 is driven within the range of the upper limit or less and the lower limit or more. This prevents the piezoelectric coil 10 from being damaged.

### <Voltage Generated in Second Piezoelectric Member 21, Etc.>

The present inventors conducted a simulation regarding whether or not the voltage generated by the second piezoelectric member 21 is a voltage whose magnitude is large enough to be measured by the displacement sensor 20.

In this simulation, two types of samples, i.e., a first sample and a second sample, were used as samples of the piezoelectric coil with a sensor 100. In the first sample, PZT was commonly used as the materials of the first piezoelectric member 12 and the second piezoelectric member 21. Meanwhile, in the second sample, PZT was used as the material of the first piezoelectric member 12, and P(VDF-TrFE) (75/25) was used as the material of the second piezoelectric member 21. Note that P(VDF-TrFE) (75/25) is a material softer than PZT.

The specific conditions for this simulation are as follows.
Number of turns of coil: basic unit for one circle
Material of core 11: SUS
Material of first piezoelectric member 12: hard PZT ceramics
Material of second piezoelectric member 21: hard
PZT ceramics (first sample): P(VDF-TrFE) (75/25) (second sample)
Number of first piezoelectric members 12: 3
Number of second piezoelectric members 21: 1
Outermost diameter of coil: 1 mm
Wrapping angle of first piezoelectric member and second piezoelectric member 21: 45°
Occupancy ratio: 99.7%
Interface between core 11 and first piezoelectric member 12 and second piezoelectric member 21: fixed

Note that the outermost diameter of a coil 2 times the outermost position of the piezoelectric coil 10 from the central axis of the piezoelectric coil 10 (see the dotted line in FIG. 1) in the radial direction. Further, the wrapping angle is an angle at which the first piezoelectric member 12 and the second piezoelectric member 21 are wrapped around the core 11, and this wrapping angle is set to 0° in a direction parallel to the length direction of the core 11. Further, the occupancy ratio is a ratio of how much the first piezoelectric member 12 and the second piezoelectric member 21 cover the surface of the core 11.

Under the above conditions, the electric field to be applied to the three first piezoelectric members 12 was changed between 0 to 1.5 [kV/mm], and the entire displacement of the piezoelectric coil with a sensor 100 (in the direction of the central axis of the coil: see the dotted line in FIG. 1) and the voltage generated by the second piezoelectric member 21 were measured by simulation.

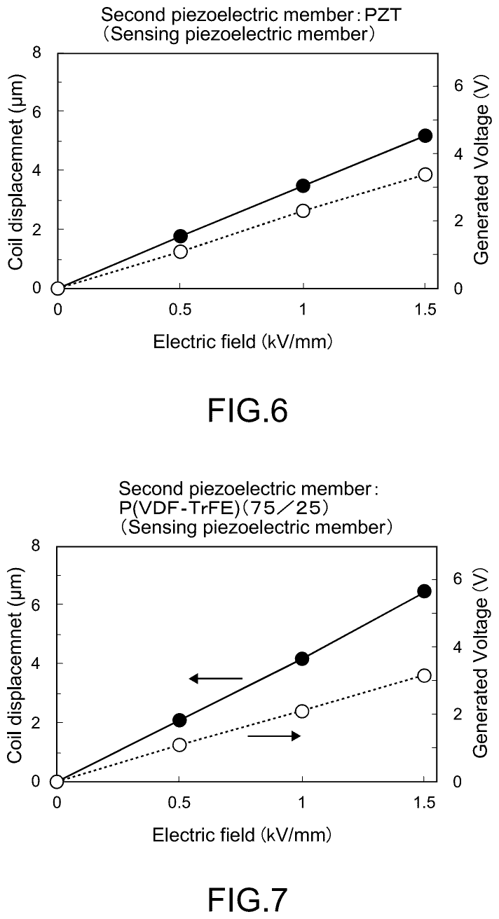

FIG. 6 is a diagram showing a simulation result in a first sample (second piezoelectric member 21: PZT). FIG. 7 is a diagram showing a simulation result in a second sample (second piezoelectric member 21: P(VDF-TrFE)).

In FIG. 6 and FIG. 7, the horizontal axis indicates the electric field applied to the first piezoelectric member 12. Further, the vertical axis on the left side indicates the displacement of the entire piezoelectric coil with a sensor 100, and the vertical axis on the right side indicates the generated voltage in the second piezoelectric member 21.

Further, in FIG. 6 and FIG. 7, the solid line graph shows a relationship between the voltage applied to the first piezoelectric member 12 and the displacement of the entire piezoelectric coil with a sensor 100. Further, the broken line graph shows a relationship between the electric field applied to the first piezoelectric member 12 and the generated voltage in the second piezoelectric member 21.

As shown in FIG. 6 and FIG. 7, in both the first sample and the second sample, when an electric field of 1 kV/mm is applied to the first piezoelectric member 12, a displacement of approximately 4 to 5 μm occurs. At this time, a voltage of approximately 2 to 3 V is generated from the second piezoelectric member 21. Therefore, it can be seen that a voltage sufficient for the displacement sensor 20 is generated from the second piezoelectric member 21.

Here, P(VDF-TrFE) used as the second piezoelectric member 21 in the second sample shown in FIG. 7 is a material softer than PZT used as the second piezoelectric member 21 in the first sample shown in FIG. 6.

Therefore, when comparing the solid line graphs in FIG. 6 and FIG. 7, the solid line graph shown in FIG. 7 has a slope steeper than that of the solid line graph shown in FIG. 6. Specifically, when the same electric field is applied to the first piezoelectric member 12 in the first sample and the second sample, the displacement of the entire piezoelectric coil with a sensor 100 in the second sample (see FIG. 7: solid line) is higher than that of the displacement of the entire piezoelectric coil with a sensor 100 in the first sample (see FIG. 6: solid line) by approximately 20%.

That is, in the second sample shown in FIG. 7, since a softer (than PZT) material such as P(VDF-TrFE) (or PLLA, etc.) is used as the material of the second piezoelectric member 21, it is possible to appropriately reduce the influence of the second piezoelectric member 21 restricting the movement of the piezoelectric coil 10 when it operates.

Meanwhile, P(VDF-TrFE) used as the second piezoelectric member 21 in the second sample shown in FIG. 7 is a material having piezoelectric performance (piezoelectric constant) slightly lower than that of PZT used as the second piezoelectric member 21 in the first sample shown in FIG. 6.

Therefore, when comparing the broken line graphs in FIG. 6 and FIG. 7, the broken line graph shown in FIG. 7 has a slope slightly gentler than that of the broken line graph shown in FIG. 6. Specifically, when the same electric field is applied to the first piezoelectric member 12 in the first sample and the second sample, a voltage generated by P(VDF-TrFE) in the second sample (see FIG. 7: broken line) is lower than the voltage generated by PZT in the first sample by approximately 5%.

That is, from the viewpoint of reducing the restriction during the operation of the piezoelectric coil 10, in the case where a softer (than PZT) material such as P(VDF-TrFE) (or PLLA, etc.) is used as the second piezoelectric member, the piezoelectric properties are slightly lower as compared with PZT or the like. However, when P(VDF-TrFE) (or PLLA) or the like is used as the second piezoelectric member, the decrease in generated voltage is approximately 5% at most as compared with the case where PZT or the like is used as the second piezoelectric member, and a voltage large enough to be measured by the displacement sensor 20 can be obtained from the second piezoelectric member 21.

### <Another Example of Signal Detection of Displacement Sensing>

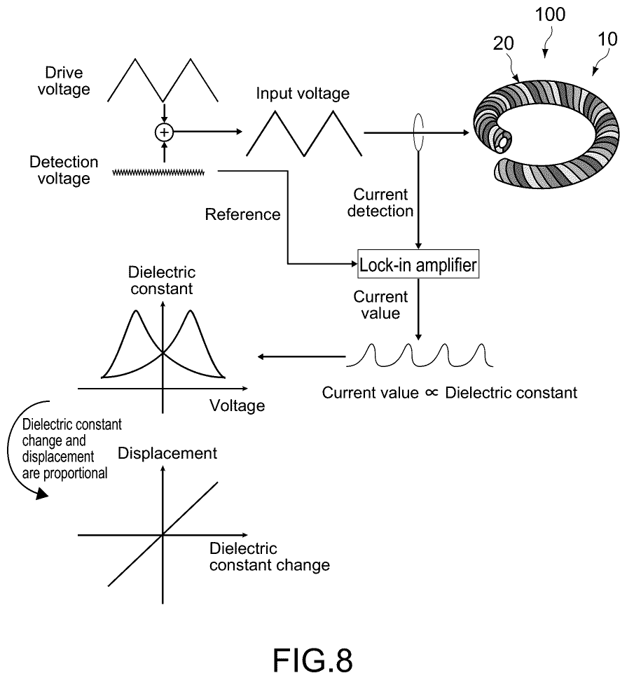

Next, another example of signal detection in displacement sensing will be described. FIG. 8 is a diagram showing another example of signal detection in displacement sensing.

In the example shown in FIG. 8, the piezoelectric coil 10 is used as a piezoelectric actuator, and the second piezoelectric member 21 drives the piezoelectric actuator together with the first piezoelectric member 12 when a voltage applied thereto. That is, in this example, the second piezoelectric member 21 has two roles as part of the displacement sensor 20 for detecting a displacement of the piezoelectric coil 10 and as part of a drive unit that drives the piezoelectric coil 10.

As shown in FIG. 8, an input voltage is generated by superimposing a detection voltage on a drive voltage. The detection voltage is lower than the drive voltage and has a higher frequency. This input voltage is applied to each of the three first piezoelectric members 12 via the first electrode (surface electrode 14) and is applied to the second piezoelectric member 21 via the second electrode (detection electrode 23).

Note that the input voltage obtained by superimposing the detection voltage on the drive voltage may be applied to only the second piezoelectric member 21. In this case, a normal drive voltage on which no detection voltage has been superimposed is input to the first piezoelectric member 12. However, in the case where the input voltage obtained by superimposing the detection voltage on the drive voltage is commonly input to the first piezoelectric member 12 and the second piezoelectric member 21, the circuit can be simplified, which is advantageous.

In accordance with the application of the input voltage, the three first piezoelectric members 12 and one second piezoelectric member 21 are distorted, and a stress is generated on the core 11. As a result, the core 11 expands and contracts in the expanding/contracting direction, and the entire piezoelectric coil with a sensor 100 expands and contracts in the expanding/contracting direction.

At this time, an output current from the second piezoelectric member 21 is extracted via the second electrode portion 22 (detection electrode 23). Then, the detection voltage is used as reference signal, a lock-in amplifier allows the same frequency component as the reference signal to pass through the filter from the output current, and only the current value of the component is extracted (lock-in detection).

This current value is in a proportional relationship with a dielectric constant of the second piezoelectric member 21. Therefore, by measuring the change in the current value, it is possible to measure the change in the dielectric constant of the second piezoelectric member 21. Further, since the change in the dielectric constant of the second piezoelectric member 21 is proportional to the piezoelectric strain of the second piezoelectric member 21 and the correspondence is 1:1, it is possible to perform sense of the displacement of the piezoelectric coil 10. As a result, it is possible to measure not only the frequency of movement of the piezoelectric coil with a sensor 100 but also the displacement itself of the piezoelectric coil with a sensor 100.

In the case of this example, typically, the same material is used for the first piezoelectric member 12 and the second piezoelectric member 21. This is because the second piezoelectric member 21 also has a role as part of the drive unit that drives the piezoelectric coil 10 and the second piezoelectric member 21 (displacement sensor 20) does not restrict the movement of the piezoelectric coil 10.

In the case where the same material is used for the first piezoelectric member 12 and the second piezoelectric member 21, there is an advantage that production of the piezoelectric coil with a sensor 100 becomes easier. Further, in the case where the same material is used for the first piezoelectric member 12 and the second piezoelectric member 21, there is an advantage that the piezoelectric performance of the piezoelectric coil with a sensor 100 can be prevented from decreasing, as compared with the case where a material that is softer than the first piezoelectric member 12 and has piezoelectric performance lower than that of the first piezoelectric member 12 is used as the second piezoelectric member 21.

### Effects, Etc.

As described above, the piezoelectric coil with a sensor 100 according to this embodiment includes: the piezoelectric coil 10 that includes the coil-shaped core 11 and the one or more first piezoelectric members 12 that are helical relative to the core 11, and is expandable and contractable in the expanding/contracting direction; and the displacement sensor 20 that detects a displacement due to expansion and contraction of the piezoelectric coil 10.

As a result, it is possible to provide the piezoelectric coil with a sensor 100 capable of performing displacement sensing for the piezoelectric coil 10 in which the first piezoelectric members 12 that are helically wound around the coil-shaped core 11.

Further, in this embodiment, the second piezoelectric member 21 helically wound around the core 11 such that the second piezoelectric member 21 is disposed alternately with the first piezoelectric member 12 in the direction along the core 11 functions as part of the displacement sensor 20. Therefore, in this embodiment, there is no need to provide another displacement sensor separately, and it is possible to provide the piezoelectric coil with a sensor 100 that is simple and can be miniaturized while having a self-sensing function.

Further, in this embodiment, by setting the number of first piezoelectric members 12 to two or more, it is also possible to improve the piezoelectric performance of the piezoelectric coil with a sensor 100.

Further, by using a material softer than the first piezoelectric member 12 as the material of the second piezoelectric member 21, it is possible to reduce the influence of the displacement sensor 20 (second piezoelectric member 21) restricting the movement of the piezoelectric coil with a sensor 100 when it operates.

Meanwhile, as the material of the second piezoelectric member 21, the same material as the first piezoelectric member 12 can also be used. In this case, production of the piezoelectric coil with a sensor 100 becomes easier, and it is possible to prevent the piezoelectric performance of the piezoelectric coil with a sensor 100 from decreasing. In particular, in the case where the lock-in detection shown in FIG. 8 is performed, it is effective to use a common material for the first piezoelectric member 12 and the second piezoelectric member 21.

Further, in the case where the piezoelectric coil with a sensor 100 is used as a piezoelectric actuator, by performing feedback control on the basis of the information regarding the displacement detected by the displacement sensor 20, it is possible to accurately drive the piezoelectric coil with a sensor 100. Note that performing such feedback control is particularly effective, because hysteresis increases and it is difficult to drive the piezoelectric coil 10 in some cases when a high voltage is applied to the first piezoelectric member 12.

Further, in the case where the piezoelectric coil with a sensor 100 is used as power generation element, it is possible to prevent the piezoelectric coil with a sensor 100 from being damaged by adjusting, on the basis of the information regarding the displacement detected by the displacement sensor 20, the external force such that the piezoelectric coil with a sensor 100 is driven within the range of, for example, the upper limit or less and the lower limit or more.

Note that although the second piezoelectric member 21 is used as the displacement sensor 20 in this embodiment, any element can be used as the displacement sensor 20 as long as the properties of the element change due to the strain of the piezoelectric coil 10 (the same applied to a second embodiment). For example, instead of the second piezoelectric member 21, a material whose resistance changes due to a strain, such as a strain gauge and a carbon composite film, may be used.

### Second Embodiment

Next, a second embodiment of the present technology will be described. Note that in the description of the second embodiment and subsequent embodiments, the respective units having configurations and functions similar to those in the above-mentioned first embodiment will be denoted by the same reference symbols, and description thereof will be simplified or omitted.

The case where the second piezoelectric member 21 is disposed in the direction along the length direction of the core 11 (see the dot-dash line in FIG. 1) with respect to the first piezoelectric member 12 has been described in the above-mentioned first embodiment. Meanwhile, in the second embodiment, a case where the second piezoelectric member 21 is disposed in a stacking direction orthogonal to the length direction of the core 11 with respect to the first piezoelectric member 12 will be described.

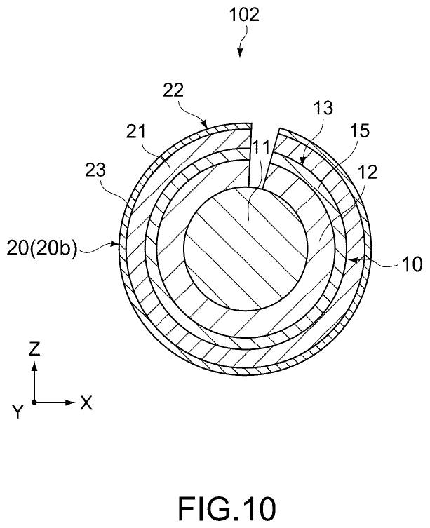

FIG. 9 is a perspective view showing a piezoelectric coil with a sensor 101 according to the second embodiment. FIG. 10 is a cross-sectional view of the piezoelectric coil with a sensor 101 in a plane perpendicular to the length direction of the core 11.

As shown in FIG. 9 and FIG. 10, the piezoelectric coil with a sensor 100 includes the piezoelectric coil 10 and a displacement sensor 20b.

The piezoelectric coil 10 the coil-shaped core 11 that is expandable and contractable in an expanding/contracting direction, the first piezoelectric member 12 helically wound around the core 11, and the first electrode portion 13 that applies an electric field in a thickness direction of the first piezoelectric member 12.

The first electrode portion 13 includes the core 11 and an internal electrode 15. One of the core 11 and the internal electrode 15 is a positive electrode, and the other is a negative electrode.

The internal electrode 15 is provided so as to cover the entire surface of the first piezoelectric member 12, and is helical relative to the core 11, similarly to the first piezoelectric member 12. Note that the internal electrode 15 is interposed between the first piezoelectric member 12 and the second piezoelectric member 21.

The displacement sensor 20b includes the second piezoelectric member 21 and the second electrode portion 22. The second piezoelectric member 21 is disposed outside the first piezoelectric member 12 in the staking direction, and is helical relative to the core 11, similarly to the first piezoelectric member 12.

The second electrode portion 22 includes the detection electrode 23, and detects the voltage generated in the thickness direction of the second piezoelectric member 21. The detection electrode 23 is provided so as to cover the entire surface of the second piezoelectric member 21, and is helical relative to the core 11, similarly to the second piezoelectric member 21.

Although the number of stacked layers in the stacking direction of the first piezoelectric member 12 is one in FIG. 9 and FIG. 10, the number of stacked layers of the first piezoelectric member 12 may be two or more and is not particularly limited.

Note that when the number of stacked layers of the first piezoelectric member 12 increases (same volume), larger output (displacement amount (strain), generated force) can be obtained even with a small applied voltage (piezoelectric actuator), or larger electric power can be obtained with a small displacement amount (strain) (power generation element).

The first piezoelectric member 12 and the second piezoelectric member 21 may be formed of the same material (e.g., in the case of lock-in detection) or may be formed of different materials. In the case where the first piezoelectric member 12 and the second piezoelectric member 21 are formed of different materials, the second piezoelectric member 21 may be formed of a material softer (lower Young's modulus) than the first piezoelectric member 12.

Although the second piezoelectric member 21 is disposed outside the first piezoelectric member 12 in the stacking direction in the example shown in FIG. 10, the second piezoelectric member 21 may be disposed inside the first piezoelectric member 12. Further, in the case where the number of stacked layers of the first piezoelectric member 12 is two or more, the second piezoelectric member 21 may be interposed between the inner first piezoelectric member 12 and the outer first piezoelectric member 12.

Note that when the second piezoelectric member 21 is disposed on the outermost side, since the second piezoelectric member 21 is distorted more than the case where the second piezoelectric member 21 is disposed inside, detection of a displacement is made easier.

### Effects, Etc.

In the second embodiment, the helical second piezoelectric member 21 disposed in the stacking direction with respect to the first piezoelectric member 12 functions as part of the displacement sensor 20b. Therefore, similarly to the first embodiment, there is no need to provide another displacement sensor separately, and it is possible to provide the piezoelectric coil with a sensor 101 that is simple and can be miniaturized while having a self-sensing function.

Further, in the second embodiment, by setting the number of stacked layers of the first piezoelectric member 12 to two or more, larger output (displacement amount (strain), generated force) can be obtained even with a small applied voltage (piezoelectric actuator), or larger electric power can be obtained with a small displacement amount (strain) (power generation element).

Further, in the second embodiment, when the second piezoelectric member 21 is disposed on the outermost side, since the second piezoelectric member 21 is distorted more than the case where the second piezoelectric member 21 is disposed inside, detection of a displacement is made easier.

### Various Modified Examples

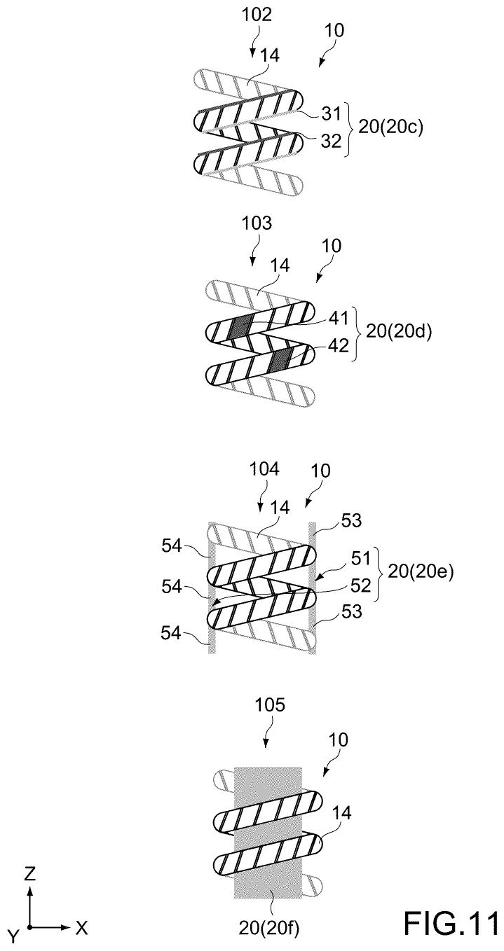

Next, piezoelectric coils with a sensor 102 to 105 according to respective modified examples of the present technology will be described. FIG. 11 is a diagram showing the piezoelectric coils with a sensor 102 to 105 according to the respective modified examples. In FIG. 11, the coils are referred to as the piezoelectric coils with a sensor 102 to 105 according to a first modified example, a second modified example, a third modified example, and a fourth modified example in order from the top.

In the first modified example to the fourth modified example, the configuration of the displacement sensor 20 differs. Note that the configuration of the piezoelectric coil 10 is common to the first modified example to the fourth modified example. This piezoelectric coil 10 includes the core 11, the first piezoelectric member 12 helically wound around the core 11, and the surface electrode 14 (first electrode portion 13) provided on the surface of the first piezoelectric member 12.

Here, the piezoelectric coil 10 has a gap in the expanding/contracting direction (Z-axis direction) due to its structure, and a hollow portion is present inside the piezoelectric coil 10 in the radial direction (direction in the XY plane) orthogonal to the expanding/contracting direction. In the first modified example to the fourth modified example, the displacement sensor 20 is disposed in such a gap or hollow portion.

Note that the first modified example to the third modified example each show an example in which the displacement sensor 20 is disposed in a gap in the expanding/contracting direction of the piezoelectric coil 10, and the fourth modified example shows an example in which the displacement sensor 20 is disposed in a hollow portion (inside the piezoelectric coil 10 in the radial direction).

### First Modified Example

With reference to the top of FIG. 11, a displacement sensor 20c of the piezoelectric coil with a sensor 102 according to the first modified example is a capacitive displacement sensor. Note that in the following description, a basic unit for one circle in the piezoelectric coil 10 will be referred to as a unit coil.

The displacement sensor 20c includes a first electrode 31 and a second electrode 32 for capacitance detection. The first electrode 31 is disposed on the lower side of the upper unit coil, and the second electrode 32 is disposed on the upper side of the lower unit coil adjacent thereto.

Note that an insulation layer is interposed between the first electrode 31 and the surface electrode 14, and similarly, an insulation layer is interposed between the second electrode 32 and the surface electrode 14.

The displacement sensor 20c may be provided in all gaps in the expanding/contracting direction of the piezoelectric coil 10 or may be provided in some of the gaps. In the case where the displacement sensors 20c are provided in some of the gaps, for example, the displacement sensors 20c may be provided in every other gap (the same applies to the second modified example).

In the first modified example, when the piezoelectric coil 10 expands and contracts in the expanding/contracting direction, the distance between the first electrode 31 and the second electrode 32 changes and the capacitance changes, so that the displacement of the piezoelectric coil with a sensor 102 can be detected.

### Second Modified Example

With reference to the second top of FIG. 11, a displacement sensor 20d of the piezoelectric coil with a sensor 103 according to the second modified example is a capacitive displacement sensor similarly to the first modified example.

The displacement sensor 20d includes a first electrode 41 and a second electrode 42 for capacitance detection. The first electrode 41 is provided so as to cover the surface of the surface electrode 14 via an insulation layer in the upper unit coil and is configured to be helically wound around the core 11 by, for example, half a circle.

Meanwhile, the second electrode 42 is provided so as to cover the surface of the surface electrode 14 via an insulation layer in the lower unit coil adjacent thereto and is configured to be helically wound around the core 11 by, for example, half a circle.

In the second modified example, similarly to the first modified example, when the piezoelectric coil 10 expands and contracts in the expanding/contracting direction, the distance between the first electrode 41 and the second electrode 42 changes and the capacitance changes, so that the displacement of the piezoelectric coil with a sensor 102 can be detected.

### Third Modified Example

With reference to the third top of FIG. 11, a displacement sensor 20e of the piezoelectric coil with a sensor 104 according to the third modified example is a displacement sensor of a piezoelectric type (piezoelectric member), a resistance type (strain gauge), or the like.

The displacement sensor 20e includes a first sensor unit 51 and a second sensor unit 52 disposed on both ends of the piezoelectric coil 10 in the radial direction with the central axis of the piezoelectric coil 10 sandwiched therebetween. Note that the reason why the first sensor unit 51 and the second sensor unit 52 are disposed on both ends in the radial direction with the central axis of the piezoelectric coil 10 sandwiched therebetween is to maintain balance during expansion and contraction of the piezoelectric coil with a sensor 104.

The first sensor unit 51 includes a plurality of first sensors 53 disposed linearly in the expanding/contracting direction of the piezoelectric coil 10. The second sensor unit 52 includes a plurality of second sensors 54 disposed linearly in the expanding/contracting direction of the piezoelectric coil 10.

The upper end of the first sensor 53 is fixed to the lower side of the upper unit coil, and the lower end of the first sensor 53 is fixed to the upper side of the lower unit coil adjacent thereto. Further, the upper end of the second sensor 54 is fixed to the lower end of the upper unit coil, and the lower end of the second sensor 54 is fixed to the upper side of the lower unit coil adjacent thereto.

In the third modified example, when the piezoelectric coil 10 expands and contracts in the expanding/contracting direction, the voltage, resistance, and the like in the first sensor 53 and the second sensor 54 change. By detecting these, the displacement of the piezoelectric coil with a sensor 104 can be detected.

Note that in the third modified example, in order to reduce the influence of the displacement sensor 20e restricting the movement of the piezoelectric coil 10, a relatively soft material (e.g., a material softer than the first piezoelectric member 12) may be used as the material of the displacement sensor 20e. For example, in the case where the displacement sensor 20e is of a piezoelectric type, a piezoelectric resin such as PVDF and PLLA may be used. In the case where the displacement sensor 20e is of a resistance type, a relatively soft strain gauge or carbon composite may be used (the same applies to the fourth modified example).

### Fourth Modified Example

With reference to the bottom of FIG. 11, a displacement sensor 20f of a piezoelectric coil with a sensor 105 according to the fourth modified example is a displacement sensor of a piezoelectric type (piezoelectric member), a resistance type (strain gauge), or the like.

The displacement sensor 20f is disposed in a hollow portion inside the piezoelectric coil 10 in the radial direction. The displacement sensor 20f has, for example, a columnar shape or cylindrical shape that is long in the expanding/contracting direction of the piezoelectric coil 10 (Z-axis direction), and the outer peripheral surface thereof is fixed to the inner peripheral surface of the piezoelectric coil 10.

In the fourth modified example, when the piezoelectric coil 10 expands and contracts in the expanding/contracting direction, the voltage, resistance, and the like in the displacement sensor 20f change. By detecting these, the displacement of the piezoelectric coil with a sensor 105 can be detected.

### Conclusion of First Modified Example to Fourth Modified Example

As described above, in the first modified example to the fourth modified example, the displacement sensors 20c to 20f are respectively disposed in the gap in the expanding/contracting direction of the piezoelectric coil 10 or the hollow portion inside the piezoelectric coil 10 in the radial direction. Even in the case where the displacement sensors 20c to 20f are provided in such portions, it is possible to provide the piezoelectric coils with a sensor 102 to 105 that are simple and can be miniaturized while having a self-sensing function, similarly to the above-mentioned first embodiment and second embodiment. Further, in the first modified example to the fourth modified example, since the displacement or the amount of deformation in the expanding/contracting direction of the piezoelectric coil 10, which changes greatly, can be directly sensed, it is possible to improve the measurement accuracy.

### <Electronic Apparatus>

The piezoelectric coils with a sensor 100 to 105 (piezoelectric actuator, power generation element) according to the present technology can be installed in various electronic apparatuses. For example, the piezoelectric coils with a sensor 100 to 105 may be used in drive systems such as a micro pump, camera focusing, an inkjet printer, a microscope stage, and a displacement magnification mechanism, or may be used as a mount for an automobile engine or a shock absorber for an automobile suspension. Note that since apparatuses including the piezoelectric coils with a sensor 100 to 105 according to the present technology are regarded as apparatuses utilizing electronic engineering, any apparatus is regarded as an electronic apparatus according to the present technology.

### Others

It should be noted that the present technology may takes the following configurations.

(1) A piezoelectric coil with a sensor, including:
a piezoelectric coil that includes a coil-shaped core and one or more first piezoelectric members that are helical relative to the core, and is expandable and contractable in an expanding/contracting direction; and
a sensor that detects a displacement due to expansion and contraction of the piezoelectric coil.
   (2) The piezoelectric coil with a sensor according to (1) above, in which
the sensor is helical relative to the core.
   (3) The piezoelectric coil with a sensor according to (2) above, in which
the sensor includes a helical second piezoelectric member.
   (4) The piezoelectric coil with a sensor according to (3) above, in which
the second piezoelectric member is disposed in a direction along the core with respect to the first piezoelectric member.
   (5) The piezoelectric coil with a sensor according to (4) above, in which
the second piezoelectric member is disposed alternately with the first piezoelectric member in the direction along the core.
   (6) The piezoelectric coil with a sensor according to (5) above, in which
the one or more first piezoelectric members include a plurality of first piezoelectric members aligned in the direction along the core.
   (7) The piezoelectric coil with a sensor according to (3) above, in which
the second piezoelectric member is disposed in a stacking direction orthogonal to a direction along the core with respect to the first piezoelectric member.
   (8) The piezoelectric coil with a sensor according to (7) above, in which
the second piezoelectric member is disposed outside the first piezoelectric member in the stacking direction.
   (9) The piezoelectric coil with a sensor according to (7) or (8) above, in which
the one or more first piezoelectric members include a plurality of first piezoelectric members stacked in the stacking direction.
   (10) The piezoelectric coil with a sensor according to any one of (3) to (9) above, in which
the first piezoelectric member and the second piezoelectric member are formed of different materials.
   (11) The piezoelectric coil with a sensor according to (10) above, in which
the second piezoelectric member is formed of a material softer than the first piezoelectric member.
   (12) The piezoelectric coil with a sensor according to any one of (3) to (9) above, in which
the first piezoelectric member and the second piezoelectric member are formed of the same material.
   (13) The piezoelectric coil with a sensor according to any one of (3) to (9) above, in which
the piezoelectric coil is a piezoelectric actuator in which the piezoelectric coil expands and contracts in the expanding/contracting direction when a voltage is applied to the first piezoelectric member, and
the second piezoelectric member drives the piezoelectric actuator together with the first piezoelectric member when a voltage is applied to the second piezoelectric member.
   (14) The piezoelectric coil with a sensor according to (13) above, in which
the voltage to be applied to the second piezoelectric member is a voltage obtained by superimposing a drive voltage for driving the piezoelectric actuator and a detection voltage for detecting a displacement of the piezoelectric actuator.
   (15) The piezoelectric coil with a sensor according to (14) above, in which
a displacement of the piezoelectric actuator is detected by lock-in detection of an output current of the second piezoelectric member with respect to the detection voltage.
   (16) The piezoelectric coil with a sensor according to (1) above, in which
the sensor is provided in a gap in the expanding/contracting direction of the piezoelectric coil or a hollow portion inside the piezoelectric coil in a radial direction orthogonal to the expanding/contracting direction.
   (17) The piezoelectric coil with a sensor according to (16) above, in which
the sensor is a sensor of a capacitive type, a piezoelectric type, or a resistance type.
   (18) The piezoelectric coil with a sensor according to any one of (1) to (17) above, in which
the piezoelectric coil is a piezoelectric actuator in which the piezoelectric coil expands and contracts in the expanding/contracting direction when a voltage is applied to the first piezoelectric member.
   (19) The piezoelectric coil with a sensor according to any one of (1) to (17) above, in which
the piezoelectric coil is a power generation element in which the first piezoelectric member generates electric power when the piezoelectric coil expands and contracts in the expanding/contracting direction due to an external force.
   (20) An electronic apparatus, including:
a piezoelectric coil with a sensor that includes
   a piezoelectric coil that includes a coil-shaped core and one or more first piezoelectric members that are helical relative to the core, and is expandable and contractable in an expanding/contracting direction, and
   a sensor that detects a displacement due to expansion and contraction of the piezoelectric coil.

### REFERENCE SIGNS LIST

10 piezoelectric coil
11 core
12 first piezoelectric member
20 displacement sensor
21 second piezoelectric member
100 to 105 piezoelectric coil with sensor

1. A piezoelectric coil with a sensor, comprising:
a piezoelectric coil that includes a coil-shaped core and one or more first piezoelectric members that are helical relative to the core, and is expandable and contractable in an expanding/contracting direction; and
a sensor that detects a displacement due to expansion and contraction of the piezoelectric coil.

2. The piezoelectric coil with a sensor according to claim 1, wherein
the sensor is helical relative to the core.

3. The piezoelectric coil with a sensor according to claim 2, wherein
the sensor includes a helical second piezoelectric member.

4. The piezoelectric coil with a sensor according to claim 3, wherein
the second piezoelectric member is disposed in a direction along the core with respect to the first piezoelectric member.

5. The piezoelectric coil with a sensor according to claim 4, wherein
the second piezoelectric member is disposed alternately with the first piezoelectric member in the direction along the core.

6. The piezoelectric coil with a sensor according to claim 5, wherein
the one or more first piezoelectric members include a plurality of first piezoelectric members aligned in the direction along the core.

7. The piezoelectric coil with a sensor according to claim 3, wherein
the second piezoelectric member is disposed in a stacking direction orthogonal to a direction along the core with respect to the first piezoelectric member.

8. The piezoelectric coil with a sensor according to claim 7, wherein
the second piezoelectric member is disposed outside the first piezoelectric member in the stacking direction.

9. The piezoelectric coil with a sensor according to claim 7, wherein
the one or more first piezoelectric members include a plurality of first piezoelectric members stacked in the stacking direction.

10. The piezoelectric coil with a sensor according to claim 3, wherein
the first piezoelectric member and the second piezoelectric member are formed of different materials.

11. The piezoelectric coil with a sensor according to claim 10, wherein
the second piezoelectric member is formed of a material softer than the first piezoelectric member.

12. The piezoelectric coil with a sensor according to claim 3, wherein
the first piezoelectric member and the second piezoelectric member are formed of the same material.

13. The piezoelectric coil with a sensor according to claim 3, wherein
the piezoelectric coil is a piezoelectric actuator in which the piezoelectric coil expands and contracts in the expanding/contracting direction when a voltage is applied to the first piezoelectric member, and
the second piezoelectric member drives the piezoelectric actuator together with the first piezoelectric member when a voltage is applied to the second piezoelectric member.

14. The piezoelectric coil with a sensor according to claim 13, wherein
the voltage to be applied to the second piezoelectric member is a voltage obtained by superimposing a drive voltage for driving the piezoelectric actuator and a detection voltage for detecting a displacement of the piezoelectric actuator.

15. The piezoelectric coil with a sensor according to claim 14, wherein
a displacement of the piezoelectric actuator is detected by lock-in detection of an output current of the second piezoelectric member with respect to the detection voltage.

16. The piezoelectric coil with a sensor according to claim 1, wherein
the sensor is provided in a gap in the expanding/contracting direction of the piezoelectric coil or a hollow portion inside the piezoelectric coil in a radial direction orthogonal to the expanding/contracting direction.

17. The piezoelectric coil with a sensor according to claim 16, wherein
the sensor is a sensor of a capacitive type, a piezoelectric type, or a resistance type.

18. The piezoelectric coil with a sensor according to claim 1, wherein
the piezoelectric coil is a piezoelectric actuator in which the piezoelectric coil expands and contracts in the expanding/contracting direction when a voltage is applied to the first piezoelectric member.

19. The piezoelectric coil with a sensor according to claim 1, wherein
the piezoelectric coil is a power generation element in which the first piezoelectric member generates electric power when the piezoelectric coil expands and contracts in the expanding/contracting direction due to an external force.

20. An electronic apparatus, comprising:
a piezoelectric coil with a sensor that includes
a piezoelectric coil that includes a coil-shaped core and one or more first piezoelectric members that are helical relative to the core, and is expandable and contractable in an expanding/contracting direction, and
a sensor that detects a displacement due to expansion and contraction of the piezoelectric coil.
